(19) United States
(12) Patent Application Publication
(10) Pub. No.: US 2011/0122572 A1
(43) Pub. Date: May 26, 2011

(54) HEAT DISSIPATION SYSTEM AND ELECTRONIC DEVICE USING THE SYSTEM

(75) Inventors: HAO-DER CHENG, Tu-Cheng (TW); HUNG-CHOU CHAN, Tu-Cheng (TW)

(73) Assignee: HON HAI PRECISION INDUSTRY CO., LTD., Tu-Cheng (TW)

(21) Appl. No.: 12/639,007

(22) Filed: Dec. 16, 2009

(30) Foreign Application Priority Data
Nov. 26, 2009 (TW) 98140254

(51) Int. Cl. G06F 1/20; H05K 5/00; F24F 7/007

(52) U.S. Cl. 361/679.48; 454/184; 454/251

(57) ABSTRACT

A heat dissipation system dissipating heat from a server includes a plurality of fans mounted on a server by a fan holder. Each fan has an inlet and an outlet. The fan holder has a framework attached to one of outer sides of the server and accommodating the fans therein. The inlets or the outlets communicate with the server through the fan holder to enable the fans to generate airflow into or out of the server.

### BACKGROUND

1. Technical Field

The present disclosure relates to a heat dissipation system and an electronic device using the system.

2. Description of Related Art

Electronic components, such as central processing units (CPUs), generate heat during normal operation, which can deteriorate their operational stability, and damage associated electronic components. Thus, the heat must be removed quickly to ensure normal operation of the CPU. An electronic device such as a server utilizing multiple heat-generating components such as CPUs therein requires a powerful heat dissipation system. The heat dissipation system for the server often includes a plurality of fans mounted inside of the server accelerating airflow therethrough. However, the heat dissipation system is inherently mounted in the server, whereby when the server requires updating or replacement, the heat dissipation system must be abandoned accordingly.

What is needed, therefore, is a heat dissipation system can be reused in multiple servers.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an assembled view of a heat dissipation system in accordance with an embodiment, applied in a server.

FIG. 2 is a partially exploded view of the heat dissipation system of FIG. 1, with a portion thereof cut away for purpose of clarity.

FIG. 3 is an assembled view of a heat dissipation system in accordance with another embodiment, applied in multiple servers.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

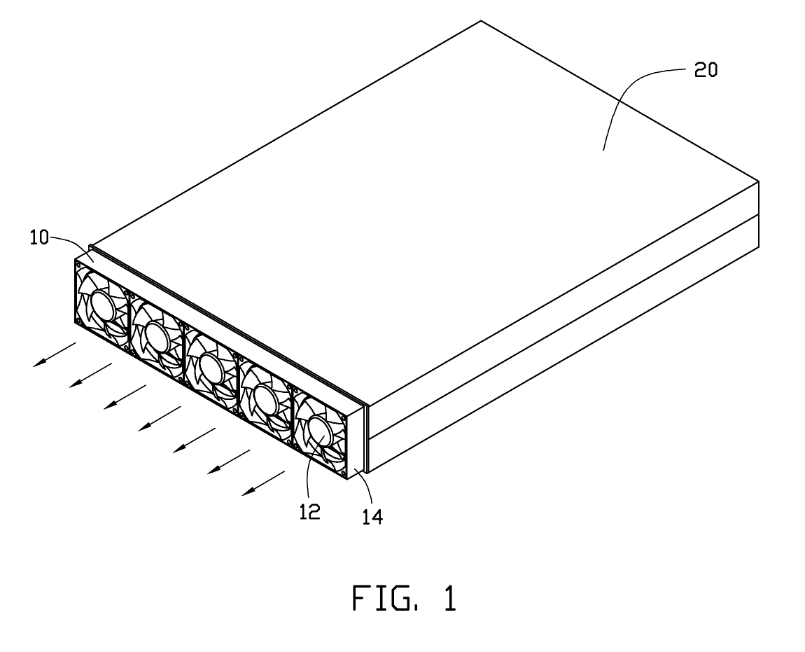

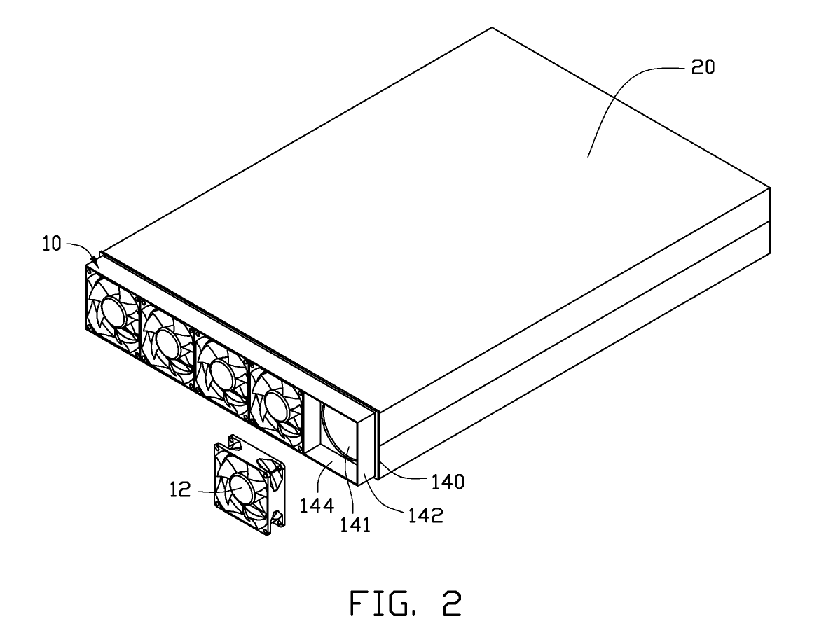

Referring to FIGS. 1 and 2, an electronic device according to an embodiment of the disclosure includes a server 20 and a heat dissipation system 10 mounted on an outer side of the server 20 to remove heat therefrom. The server 20 has different configurations in different embodiments. In this embodiment of the disclosure, the server 20 is a 2U server of standard 2U size.

The heat dissipation system 10 includes a plurality of fans 12 and a fan holder 14 securing the fans 12 to an outer side of the server 20 to generate airflow. The fans 12 are axial flow fans and generate airflow in a direction parallel to the rotation axes thereof. Each fan 12 has an air inlet and an air outlet for airflow. The air inlets or outlets of the fans 12 fully communicate with an inner cavity of the server 20 through the fan holder 10.

The fan holder 14 comprises a mounting plate 140 attached to the outer side of the server 20 and a framework 142 fixed on an outer side of the mounting plate 140. In this embodiment of the disclosure, the mounting plate 140 is attached to and wholly covers a rear side of the server 20 which is hollow to allow airflow generated by the fans 10 therethrough. A plurality of vents 141 is defined in the mounting plate 140 and arranged evenly in a line on the rear side of the server 20. A plurality of pane units 144 are formed in the framework 142 and arranged in a line continuously along the rear side of the server 20. Each vent 141 in the mounting plate 140 corresponds to one pane unit 144 and enables the pane unit 144 to communicate with a cavity inside the server 20 through the vent 141 and the rear side of the server 20. Each vent 141 is circular and is of a size similar to the air outlet or inlet of the fan 12.

In use, the fans 12, fitted in the pane units 144 of the framework 142 and abutting an outer side of the mounting plate 140, face the vents 141 of the mounting plate 140 and generate airflow into or from the server 20 through the vents 141. Each pane unit 144 has a configuration and size consistent with that of the fan 12, securely accommodating one thereof. The fans 12 mounted outside of the server 20 easily generate airflow through the server 20, exhausting heat generated thereby to the exterior, thus lowering internal temperature of the server 20.

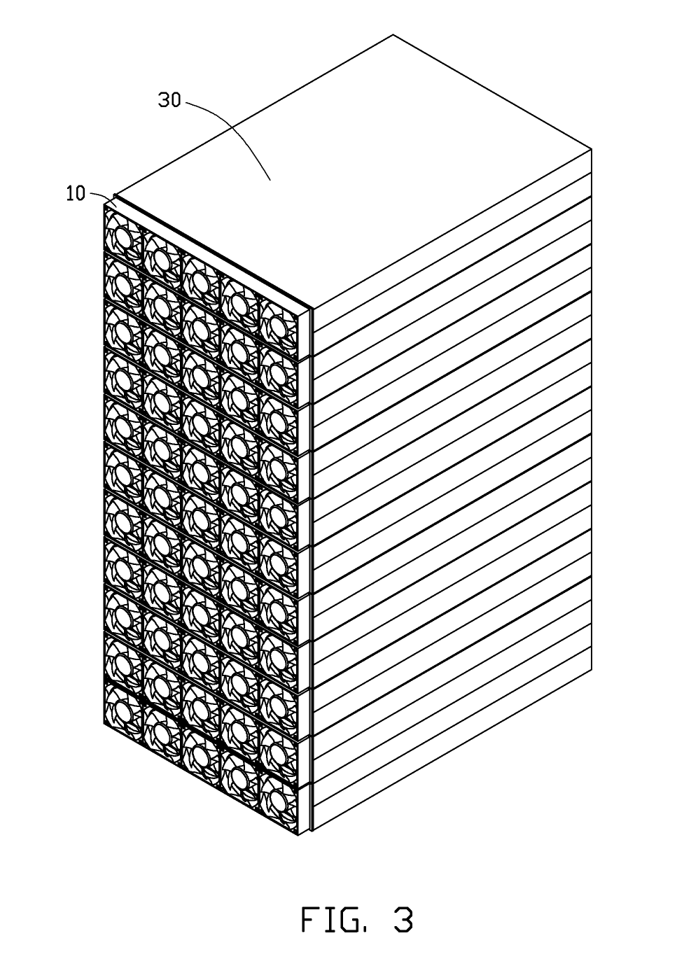

Referring to FIG. 3, a heat dissipation system 40 is applied in a server 30, being much larger than server 20. The heat dissipation system 40 is formed by multiple heat dissipation systems 10 of the above embodiment grouped and coupled together to accommodate server 30 of multiple U size.

According to the disclosure, a heat dissipation system is detachably coupled to one side of a server and can be reused with a different server when removed from the original server. In addition, fans mounted outside of the server by the fan holder 14 can be replaced as needed to increase airflow in the server with no need for available space consideration inside the server.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A heat dissipation system dissipating heat from a server, comprising:
a plurality of fans, each fan comprising an inlet and an outlet; and
a fan holder securing the fans onto an outer side of the server;
wherein the inlets and outlets communicate with the server through the fan holder and conduct airflow into or out of the server.

2. The heat dissipation system of claim 1, wherein the fans comprise axial flow fans generating airflow parallel to the rotation axes thereof with the air inlets and outlets of the fans communicating with the server through the fan holder.

3. The heat dissipation system of claim 1, wherein a plurality of vents is defined in the fan holder adjacent to the fans received in the fan holder, with each vent communicating with an inner cavity of the server and the air inlet or outlet of one of the fans.

4. The heat dissipation system of claim 3, wherein the fan holder comprises a mounting plate attached to one outer side of the server, on which the vents are defined.

5. The heat dissipation system of claim 4, wherein the fans abut an outer side of the mounting plate.

6. The heat dissipation system of claim 3, wherein the fan holder comprises a framework fixed to an outer side of the mounting plate and in which the fans are received.

7. The heat dissipation system of claim 6, wherein a plurality of pane units is formed in the framework and accommodate the fans therein, respectively.

8. The heat dissipation system of claim 7, wherein the pane units are arranged continuously along the length of the outer side of the server and cover all of one of the outer sides of the server.

9. The heat dissipation system of claim 7, wherein the pane units are arranged in multiple arrays and cover all of one of the outer sides of the server.

10. An electronic device, comprising:
a server defining an inner cavity therein;
a plurality of fans, each fan having an inlet and an outlet; and
a fan holder attached to one outer side of the server and accommodating the fans therein;
wherein the inlets or the outlets communicate with the inner cavity of the server through the fan holder to allow airflow from the fans into or out of the server.

11. The electronic device of claim 10, wherein the fan holder comprises a mounting plate located between one outer side of the server and the framework, with the fans abutting an outer side of the mounting plate.

12. The electronic device of claim 11, wherein a plurality of vents is defined in the mounting plate, each vent communicating with the server and the air inlet or outlet of one of the fans.

13. The electronic device of claim 12, wherein the fans are axial flow fans generating airflow parallel to rotation axes thereof, and the air inlets or outlets of the fans communicating with the server through the vents.

14. The electronic device of claim 12, wherein a plurality of pane units is formed in the framework and accommodates the fans therein, respectively.

15. The electronic device of claim 14, wherein the pane units are arranged continuously along the length of the outer side of the server and cover all of one outer side of the server.

16. The electronic device of claim 14, wherein the pane units are arranged in multiple arrays and cover all of one outer side of the server.
